(19) United States
(12) Patent Application Publication
(10) Pub. No.: US 2019/0318864 A1
(43) Pub. Date: Oct. 17, 2019

(54) PLANAR TRANSFORMER

(71) Applicants: Hyundai Motor Company, Seoul (KR); Kia Motors Corporation, Seoul (KR)

(72) Inventors: In Yong Yeo, Bucheon (KR); Jin Myeong Yang, Seongnam (KR); Jae Eun Cha, Gwangmyeong (KR); Dae Woo Lee, Incheon (KR); Woo Young Lee, Yongin (KR)

(21) Appl. No.: 16/141,312

(22) Filed: Sep. 25, 2018

(30) Foreign Application Priority Data
Apr. 13, 2018 (KR) 10-2018-0043153

(51) Int. Cl. H01F 27/28; H01F 27/32; H01F 30/06; H01F 17/00; H05K 1/16

(52) U.S. Cl. CPC H01F 27/2804; H01F 27/324; H01F 30/06; H01F 2027/2809; H05K 1/165; H01F 2027/2819; H01F 17/0006

(57) ABSTRACT

A planar transformer according to the present disclosure can include: at least one pair of cores arranged vertically and symmetrically; and a printed circuit board assembly including primary printed circuit boards having coil patterns forming a primary wiring and secondary printed circuit boards having coil patterns forming a secondary wiring, the secondary printed circuit boards respectively disposed over or under the primary printed circuit boards. The coil patterns of the primary printed circuit boards and the coil patterns of the secondary printed circuit boards can be alternately stacked.

### CROSS-REFERENCE TO RELATED APPLICATION

The present application claims the benefit of priority to Korean Patent Application No. 10-2018-0043153, filed on Apr. 13, 2018 in the Korean Intellectual Property Office, the entire contents of which are incorporated herein for all purposes by reference.

### BACKGROUND OF THE DISCLOSURE

### 1. Technical Field

The present disclosure relates to a planar transformer and, more particularly, to a planar transformer that minimizes leakage inductance and parasitic capacitance components between a primary printed circuit board and a secondary printed circuit board.

### 2. Description of the Prior Art

Recently, technologies relating to “eco-friendly” vehicles that use electric energy as power for driving have been actively developed to cope with the crises of air pollution and depletion of oil reserves. Eco-friendly vehicles include, for instance, a hybrid electric vehicle, a fuel cell electric vehicle, and an electric vehicle.

Eco-friendly vehicles typically include a high-voltage battery for driving the vehicle and a low-voltage battery for driving electric devices within the vehicle. That is, the electrical energy of the high-voltage battery is used as power for the vehicle, while the electrical energy of the low-voltage battery is used as power for the electric devices.

Further, eco-friendly vehicles may include a circuit for power conversion and circuits for charging the batteries. A transformer is provided for the circuits in many cases, and recently, studies for replacing the transformer with a planar transformer to reduce manufacturing costs and make the manufacturing process easier have been actively conducted.

Conventional planar transformers can include a sequential stack of a secondary printed circuit board (i.e., a circuit board having a coil pattern forming a secondary wiring), a primary printed circuit board (i.e., a circuit board having a coil pattern forming a primary wiring), a primary printed circuit board, and a secondary printed circuit board. The coil patterns on the primary printed circuit boards and the coil patterns on the secondary printed circuit boards may be vertically aligned.

Problematically, parasitic capacitance between the primary printed circuit board and the secondary printed circuit board increases, so the resonance frequency is reduced. As a result, the switching frequency cannot be increased effectively. Further, in conventional planar transformers, there is a large leakage inductance between the primary printed circuit board and the secondary printed circuit board, thereby increasing duty loss.

### SUMMARY OF THE DISCLOSURE

The present disclosure has been made in order to solve the above-mentioned problems in the related art. An aspect of the present disclosure is to provide a planar transformer that can minimize leakage inductance and parasitic capacitance between a primary printed circuit board and a secondary printed circuit board.

In accordance with embodiments of the present disclosure, a planar transformer can include: at least one pair of cores arranged vertically and symmetrically; and a printed circuit board assembly including primary printed circuit boards having coil patterns forming a primary wiring and secondary printed circuit boards having coil patterns forming a secondary wiring, the secondary printed circuit boards respectively disposed over or under the primary printed circuit boards. The coil patterns of the primary printed circuit boards and the coil patterns of the secondary printed circuit boards can be alternately stacked.

The primary printed circuit boards may include at least an upper primary printed circuit board and a lower primary printed circuit board.

The secondary printed circuit boards may include at least an upper secondary printed circuit board and a lower secondary printed circuit board.

In the printed circuit board assembly, the upper secondary printed circuit board may be disposed under the upper primary printed circuit board, the lower primary printed circuit board may be disposed under the upper secondary printed circuit board, and the lower secondary printed circuit board may be disposed under the lower primary printed circuit board.

In the printed circuit board assembly, the upper primary printed circuit board may be disposed under the upper secondary printed circuit board, the lower secondary printed circuit board may be disposed under the upper primary printed circuit board, and the lower primary printed circuit board may be disposed under the lower secondary printed circuit board.

The planar transformer may further include an insulating layer formed between the primary printed circuit boards and the secondary printed circuit boards.

The planar transformer may further include a power signal supplier electrically connected to the primary printed circuit boards to supply a power signal.

The planar transformer may further include a power signal output unit electrically connected to the secondary printed circuit boards to output a power signal transformed by the coil patterns of the secondary printed circuit boards.

The coil patterns of the primary printed circuit boards and the coil patterns of the secondary printed circuit boards may be alternately stacked such that first ends and second ends of the coil patterns of the primary printed circuit boards and first ends and second ends of the coil patterns of the secondary printed circuit boards are positioned in the same lines, respectively.

According to the present disclosure, since a plurality of secondary printed circuit boards having coil patterns forming a secondary wiring are disposed respectively over or under a plurality of primary printed circuit boards having coil patterns forming a primary wiring, coupling between the primary printed circuit boards and the secondary printed circuit boards is increased and leakage inductance is reduced. Therefore, duty loss can be decreased. Accordingly, the range of the input or output voltage of a transformer can be increased.

Further, according to the present disclosure, since the coil patterns of the primary printed circuit boards and the coil patterns pf the secondary printed circuit boards are alternately stacked, the parasitic capacitance between the primary printed circuit boards and the secondary printed circuit boards can be reduced. Accordingly, the switching frequency can be increased by increasing the resonance frequency.

Further, as the switching frequency is increased, the filter size in the transformer can be reduced.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a view showing an external appearance of a planar transformer according to embodiments of the present disclosure;

FIG. 2 is a view showing a structure of the planar transformer according to embodiments of the present disclosure;

FIG. 3 is a view showing another structure of the planar transformer according to embodiments of the present disclosure;

FIG. 4 is a circuit diagram of a planar transformer according to embodiments of the present disclosure; and

FIG. 5 is a diagram showing a duty loss period in a planar transformer according to embodiments of the present disclosure.

It should be understood that the above-referenced drawings are not necessarily to scale, presenting a somewhat simplified representation of various preferred features illustrative of the basic principles of the disclosure. The specific design features of the present disclosure, including, for example, specific dimensions, orientations, locations, and shapes, will be determined in part by the particular intended application and use environment.

### DETAILED DESCRIPTION OF THE EMBODIMENTS

Hereinafter, embodiments of the present disclosure will be described in detail with reference to the accompanying drawings. As those skilled in the art would realize, the described embodiments may be modified in various different ways, all without departing from the spirit or scope of the present disclosure. Further, throughout the specification, like reference numerals refer to like elements.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

A planar transformer according to embodiments of the present disclosure is described hereafter with reference to the accompanying drawings.

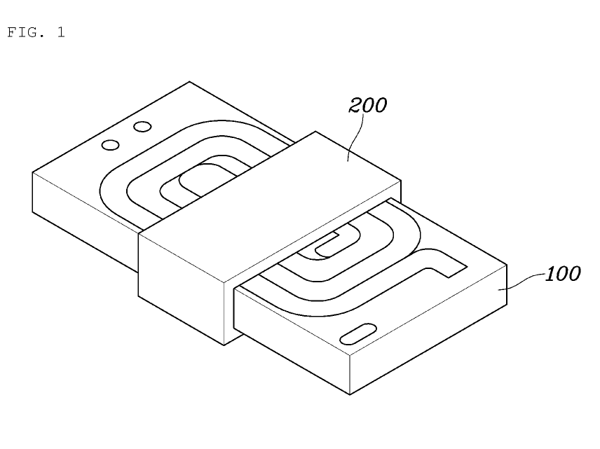

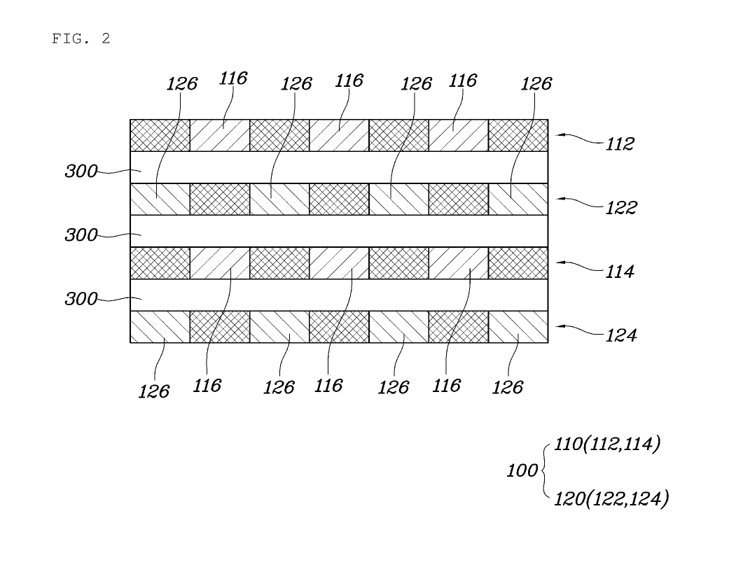

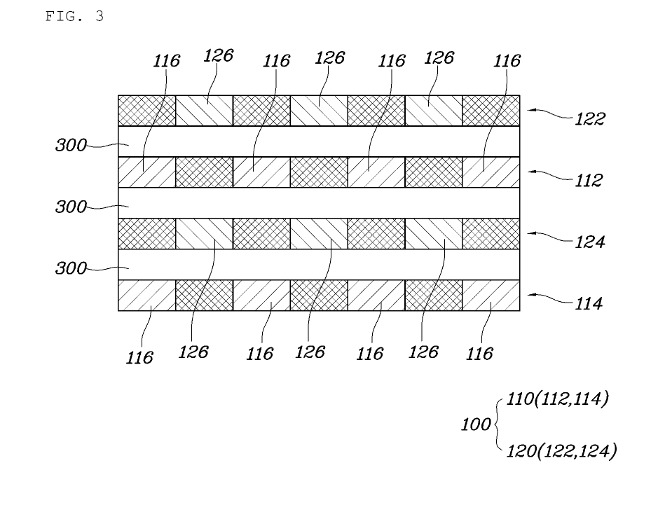

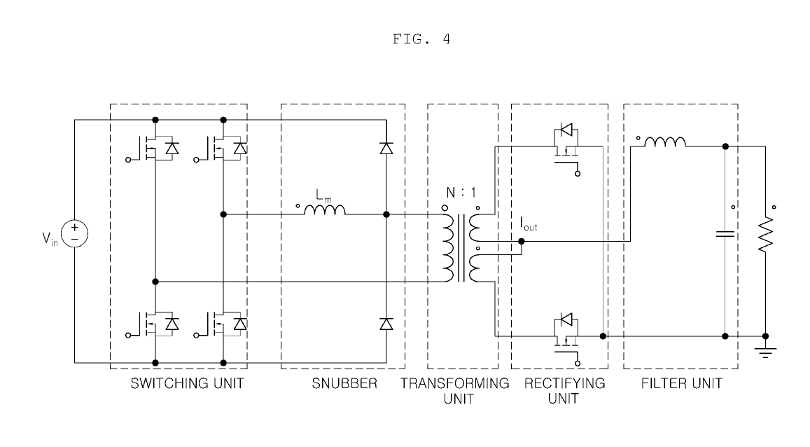

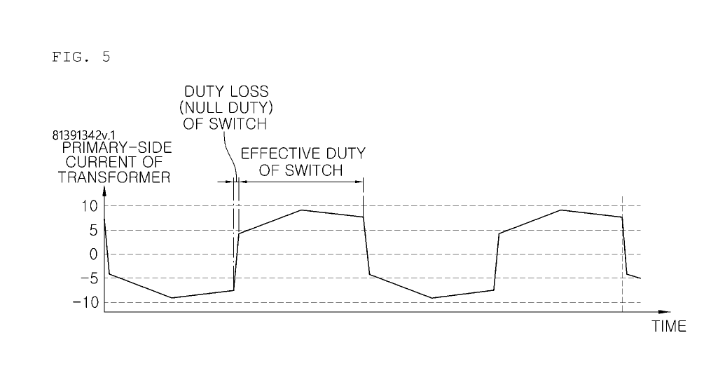

FIG. 1 is a view showing an external appearance of a planar transformer according to embodiments of the present disclosure, FIG. 2 is a view showing a structure of the planar transformer according to embodiments of the present disclosure, FIG. 3 is a view showing another structure of the planar transformer according to embodiments of the present disclosure, FIG. 4 is a circuit diagram of a planar transformer according to embodiments of the present disclosure, and FIG. 5 is a diagram showing a duty loss period in a planar transformer according to embodiments of the present disclosure.

As shown in FIG. 1, a planar transformer according to embodiments of the present disclosure may include a core 200 and a printed circuit board assembly 100, and though not shown in FIG. 1, it may further include an insulating layer 300, a power signal supplier 400, and a power signal output unit 500. The detailed configuration of the planar transformer according to embodiments of the present disclosure is described in more detail hereafter.

The core 200 is provided to induce a magnetic field and may be provided in pair to be vertically symmetric. That is, the core 200 may include a top core and a bottom core.

The printed circuit board assembly 100 may include a plurality of primary printed circuit boards 110 and a plurality of secondary printed circuit boards 120.

In detail, coil patterns forming a primary wiring may be formed on the primary printed circuit boards 110. In more detail, the primary printed circuit boards 110 may include, at least, an upper primary printed circuit board 112 and a lower primary printed circuit board 114. Primary wiring coil patterns 116 on the primary printed circuit boards 110 may be electrically connected with a coil on a different printed circuit board through via holes (not shown) at the edge of the board. That is, the primary winding coil patterns 116 on the primary printed circuit boards 110 may be electrically connected with secondary winding coils 126 on the secondary printed circuit boards 120 through via holes (not shown).

Further, coil patterns forming a secondary wiring may be formed on the secondary printed circuit boards 120. In more detail, the secondary printed circuit boards 120 may include, at least, an upper secondary printed circuit board 122 and a lower secondary printed circuit board 124. Secondary wiring coil patterns 126 on the secondary printed circuit boards 120 may be electrically connected with a coil on a different printed circuit board through via holes (not shown) at the edge of the board. That is, the secondary winding coil patterns 126 on the secondary printed circuit boards 120 may be electrically connected with the primary winding coil patterns 116 on the primary printed circuit boards 110 through via holes (not shown).

Referring to FIGS. 2 and 3, in the printed circuit board assembly 100, the secondary printed circuit boards 120 may be disposed respectively over or under the primary printed circuit boards 110. In detail, the design of the printed circuit assembly 100, which can vary as described herein. For example, as shown in FIG. 2, the upper secondary printed circuit board 122 may be disposed under the upper primary printed circuit board 112, the lower primary printed circuit board 114 may be disposed under the upper secondary printed circuit board 122, and the lower secondary printed circuit board 124 may be disposed under the lower primary printed circuit board 114.

In another example, as shown in FIG. 3, the upper primary printed circuit board 112 may be disposed under the upper secondary printed circuit board 122, the lower secondary printed circuit board 124 may be disposed under the upper primary printed circuit board 112, and the lower primary printed circuit board 114 may be disposed under the lower secondary printed circuit board 124.

Referring next to FIGS. 4 and 5, there is a duty loss period in which the current flowing through a transformer changes to a positive value and a negative value and the duty loss period is associated with leakage inductance L1, as in Equation 1, produced below. The duty loss period, which is a duty loss time, may mean a null duty period.

$${T}_{Dutyloss} = \frac{Ll \times 2 \times {I}_{OUT}}{N \times {V}_{IN}} \qquad [ Equation 1 ]$$

Here, T_{duty loss}: duty loss time, Iₒᵤₜ: output current, Ll: leakage inductance, and Vin: input voltage

Referring again to FIG. 1, the duty loss time is in proportion to the leakage inductance L1, so when the leakage inductance L1 decreases, the duty loss time reduces and the effective duty period can also increase, and accordingly, the input/output voltage range of the transformer can be increased. That is, when the leakage inductance L1 decreases, the null duty period reduces and the effective duty period increases, so the input/output voltage range of the transformer can be increased.

As described above, since a plurality of secondary printed circuit boards 120 having coil patterns forming a secondary wiring are disposed respectively over or under a plurality of primary printed circuit boards 110 having coil patterns forming a primary wiring, coupling between the primary printed circuit boards and the secondary printed circuit boards is increased and leakage inductance is reduced, so duty loss can be decreased. Accordingly, the range of the input or output voltage of the transformer can be increased.

In addition, an insulating layer 300 may be formed between the primary printed circuit boards 110 and the secondary printed circuit boards 120. The insulating layer 300 insulates the primary printed circuit boards 110 and the secondary printed circuit boards 120 from each other. Depending on the design of the printed circuit board assembly 100, the insulating layer 300 may be a prepreg, and/or may be formed in various shapes including a circle, an ellipse, a polygon, etc.

As shown in FIGS. 2 and 3, in the printed circuit board assembly 100, the primary wiring coil patterns 116 on the primary printed circuit boards 110 and the secondary wiring coil patterns 126 on the secondary printed circuit boards 120 may be alternately stacked. In detail, the primary wiring coil patterns 116 on the primary printed circuit boards 110 and the secondary wiring coil patterns 126 on the secondary printed circuit boards 120 are alternately stacked such that first ends and second ends of the primary wiring coil patterns 116 on the primary printed circuit boards 110 are in the same lines as second ends and first ends of the secondary wiring coil patterns 126 on the secondary printed circuit board 120. In other words, the primary wiring coil patterns 116 and the secondary wiring coil patterns 126 may be alternately stacked not to vertically overlap each other in the same lines.

As described above, since the primary wiring coil patterns 116 on the primary printed circuit boards 110 and the secondary wiring coil patterns 126 on the secondary printed circuit boards 120 are alternately stacked, the distances between the primary wiring coil patterns 116 and the secondary wiring coil patterns 126 are increased, so the parasitic capacitance between the primary printed circuit boards 110 and the secondary printed circuit boards 120 can be reduced. Accordingly, the resonance frequency can be increased, and consequently, the switching frequency of the transformer can be increased.

In general, when a transformer is designed, the switch frequency in the transformer should be designed smaller than the resonance frequency, and as the resonance frequency is increased, the switching frequency can be increased. In other words, according to embodiments of the present disclosure, since the primary wiring coil patterns 116 on the primary printed circuit boards 110 and the secondary wiring coil patterns 126 on the secondary printed circuit boards 120 are alternately stacked, as described above, the parasitic capacitance between the primary printed circuit board and the secondary printed circuit board can be reduced. Accordingly, the resonance frequency can be increased, and as a result, the switching frequency in the transformer can be increased. Further, as the switching frequency is increased, the filter size in the transformer can be reduced. For example, when the switching frequency is doubled, the inductance in an LC filter in the transformer can be halved.

The power signal supplier 400 is electrically connected to the primary printed circuit boards 110 and supplies a power signal. For example, the power signal supplier 400 may be electrically connected to the ends, which are exposed to the outside, of the primary printed circuit boards 110, so it can provide electricity to the primary printed circuit boards 110. Further, the power signal supplier 400 may be made of metal having high conductivity to efficiently and smoothly supply a power signal to the primary printed circuit boards 110.

The power signal output unit 500 is electrically connected to the secondary printed circuit boards 120 and outputs a power signal transformed by the secondary wiring coil patterns 126. For example, the power signal output unit 500 may be electrically connected to the ends, which are exposed to the outside, of the secondary printed circuit boards 120. Further, the power signal output unit 500 may be made of metal having high conductivity to effectively and smoothly output a power signal transformed by the secondary printed circuit boards 120.

As described above, since a plurality of secondary printed circuit boards having coil patterns forming a secondary wiring are disposed respectively over or under a plurality of primary printed circuit boards having coil patterns forming a primary wiring, coupling between the primary printed circuit boards and the secondary printed circuit boards is increased and leakage inductance is reduced, so duty loss can be decreased. Accordingly, the range of the input or output voltage of a transformer can be increased.

Further, according to embodiments of the present disclosure, since the coil patterns on the primary printed circuit boards and the coil patterns on the secondary printed circuit boards are alternately stacked, the parasitic capacitance between the primary printed circuit boards and the secondary printed circuit boards can be reduced. Accordingly, the switching frequency can be increased by increasing the resonance frequency. Further, as the switching frequency is increased, the filter size in the transformer can be reduced.

While the contents of the present disclosure have been described in connection with what is presently considered to be exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A planar transformer comprising:
at least one pair of cores arranged vertically and symmetrically; and
a printed circuit board assembly including primary printed circuit boards having coil patterns forming a primary wiring and secondary printed circuit boards having coil patterns forming a secondary wiring, the secondary printed circuit boards respectively disposed over or under the primary printed circuit boards,
wherein the coil patterns of the primary printed circuit boards and the coil patterns of the secondary printed circuit boards are alternately stacked.

2. The planar transformer of claim 1, wherein the primary printed circuit boards include at least an upper primary printed circuit board and a lower primary printed circuit board.

3. The planar transformer of claim 2, wherein the secondary printed circuit boards include at least an upper secondary printed circuit board and a lower secondary printed circuit board.

4. The planar transformer of claim 3, wherein, in the printed circuit board assembly, the upper secondary printed circuit board is disposed under the upper primary printed circuit board, the lower primary printed circuit board is disposed under the upper secondary printed circuit board, and the lower secondary printed circuit board is disposed under the lower primary printed circuit board.

5. The planar transformer of claim 3, wherein, in the printed circuit board assembly, the upper primary printed circuit board is disposed under the upper secondary printed circuit board, the lower secondary printed circuit board is disposed under the upper primary printed circuit board, and the lower primary printed circuit board is disposed under the lower secondary printed circuit board.

6. The planar transformer of claim 1, further comprising an insulating layer formed between the primary printed circuit boards and the secondary printed circuit boards.

7. The planar transformer of claim 1, further comprising a power signal supplier electrically connected to the primary printed circuit boards to supply a power signal.

8. The planar transformer of claim 1, further comprising a power signal output unit electrically connected to the secondary printed circuit boards to output a power signal transformed by the coil patterns of the secondary printed circuit boards.

9. The planar transformer of claim 1, wherein the coil patterns of the primary printed circuit boards and the coil patterns of the secondary printed circuit boards are alternately stacked such that first ends and second ends of the coil patterns of the primary printed circuit boards and first ends and second ends of the coil patterns of the secondary printed circuit boards are positioned in the same lines, respectively.
